(19) United States
(12) Patent Application Publication
(10) Pub. No.: US 2004/0263151 A1
(43) Pub. Date: Dec. 30, 2004

(54) Current sensor with a control device

(76) Inventors: Walter Zein, Metzingen (DE); Gerhard Holzwarth, Pfullingen (DE); Martin Knapp, Kirchentellinsfurt (DE)

Correspondence Address: STRIKER, STRIKER & STENBY, 103 East Neck Road, Huntington, NY, 11743, US

(21) Appl. No.: 10/873,966

(22) Filed: Jun. 22, 2004

(30) Foreign Application Priority Data
Jun. 24, 2003 (DE) 103 28 207.6

(51) Int. Cl. G01R 1/00

(52) U.S. Cl. 324/126

(57) ABSTRACT

A current sensor has a yoke with an air gap, a magnetic field probe arranged in the air gap, a circuit carrier on which the magnetic field probe is mounted, the magnetic field probe being mounted so that overlap a recess of the circuit carrier, and a magnetic flux of the yoke being oriented in the recess substantially perpendicularly to the circuit carrier.

### BACKGROUND OF THE INVENTION

The present invention relates to current sensors.

More particularly, it relates to a current sensor with a yoke with an air gap, a magnetic field probe arranged in the air gap, and a circuit carrier, on which the magnetic field probe is mounted. Such a current sensor can be used for example in an electrical control device, in particular for a motor vehicle, and forms an integrated component of such a device.

A current sensor for measuring a current which flows to a conductor is disclosed in the European patent document EP 0 815 456 B1. This current sensor includes a magnetic yoke with an air gap, as well as a parallelepiped-shaped magnetic field probe arranged in the air gap, and a circuit carrier which carries an electrical switching circuit formed for amplification of an output signal of the above mentioned magnetic field probe. The circuit carrier has a cutoff region. The cutoff region serves for receiving the conductor which is wound around the yoke to form a winding.

In the above described current sensor, the parallelepiped-shaped probe is mounted with its small side on the circuit carrier, and extends vertically and perpendicularly from the circuit carrier for insertion into the air gap of the yoke. The yoke is plugged on the pin which extends perpendicular from the circuit carrier. This construction makes the current sensor sensitive to mechanical vibrations and loads, since a small movement of the yoke relative to the circuit carrier suffices to break the magnetic field probe from the circuit carrier or at least damage the electrical contacts between it and the electrical carrier.

### SUMMARY OF THE INVENTION

Accordingly, it is an object of the present invention to provide a current sensor which avoids the disadvantages of the prior art.

More particularly, it is an object of the present invention to provide a current sensor which is especially robust and insensitive to vibrations or other types of external mechanical force applications.

In keeping with these objects and with others which will become apparent hereinafter, one feature of the present invention resides, briefly stated, in a current sensor, comprising a yoke with an air gap; a magnetic field probe arranged in said air gap; a circuit carrier on which said magnetic field probe is mounted, said magnetic field probe being mounted so that it overlaps a recess of said circuit carrier, and a magnetic flux of said yoke in said recess being oriented substantially perpendicularly to said circuit carrier.

Due to the mounting of the magnetic field probe which overlaps the recess, in the inventive current sensor very high lever moment is required to break the magnetic field probe, which is for example a Hall probe, from the circuit carrier. Since the magnetic field probe overlaps the recess of the circuit carrier, the circuit carrier does not affect either a magnetic flux through the probe or its measuring results.

In accordance with a preferable embodiment of the current sensor, the yoke is lowered in the recess of the circuit carrier to minimize the width of the air gap of the yoke.

In accordance with a further embodiment of the present invention, the recess can be formed as a window in the circuit carrier.

In accordance with a further embodiment of the present invention, the recess of the circuit carrier can also be open at its edge.

In accordance with another embodiment of the present invention, the yoke can be formed as a single-piece integral yoke.

It is however preferable to provide a multi-part, in particular a two-part yoke, since in this case a mounting of the current sensor in a housing is especially simple and fast, since the yoke does not have to be inserted completely in the housing, but instead only a corresponding partial segment. As a result, a handling space is provided for insertion of the other components, since the yoke as a whole does not interfere on the way.

In accordance with another embodiment of the present invention, the multi-part yoke can have a groove-key connection.

In a further embodiment of the present invention, a conductor rectilinearly passes through the yoke. The yoke detects the magnetic field generated by the conductor and concentrates it on the magnetic field probe. Simultaneously, it screens the control circuit located outside of the yoke from the magnetic field of the conductor. Thereby the conductor can be formed for example as a robust current rail, that can lead to high electrical current intensities. It is possible to provide the conductor which is anchored on the housing.

In accordance with an especially favorable further embodiment of the present invention, the yoke has a pin in the air gap, which engages in the cutout of the circuit carrier.

It is also especially advantageous when the circuit carrier carries a further processing circuit for processing the measuring results, provided from the magnetic field probe.

The further processing device can be formed for example as a control device of a motor vehicle. With such a control device, the current sensor can be used for example for monitoring the charging condition of a battery by measuring a battery current. Such a monitoring is especially important in so-called “x-by-Wire” motor vehicles, in which their vital functions, such as steering, brake, coupling, or gas, are electrically controlled, since in this case a disturbance of the battery can lead to failure of the functions, and therefore an operational weakness of the battery must be recognized before such a failure.

It is advantageous when the yoke has a winding for demagnetization of the yoke. If the yoke is composed of partial segments, then the winding can be arranged on one of the partial segments.

The novel features which are considered as characteristic for the present invention are set forth in particular in the appended claims. The invention itself, however, both as to its construction and its method of operation, together with additional objects and advantages thereof, will be best understood from the following description of specific embodiments when read in connection with the accompanying drawings.

### BRIEF DESCRIPTION OF THE DRAWINGS

FIG. 1 is a view showing a cross-section through a control device with an inventive current sensor;

FIG. 2 is a view showing components of the control device and of the inventive current sensor in a perspective; and

FIG. 3 is a view showing a yoke and a circuit carrier of a further embodiment of the current sensor in accordance with the present invention.

### DESCRIPTION FO TH PREFERRED EMBODIMENTS

Figure shows a cross-section of a control device with a current sensor 2 in accordance with the present invention. The current sensor 2 has a yoke composed of a ferromagnetic material, such as substantially ferrite-filled silicon. It is formed in the shown embodiment as a two-part sensor including a lower partial segment 4 and an upper partial segment 5. A Hall-probe 6 forms a magnetic field probe. It is mounted on a circuit carrier 1 and fills an air gap of the yoke.

The circuit carrier 1 can be of any known art, for example a printed circuit, a metal or a ceramic substrate. The lower partial segment 4 and the upper partial segment 5 of the yoke are joined with one another by a groove-key connection 7.

The winding 10 is provided on the upper partial segment 5, at the side of the groove-key connection 7 of the yoke. It is wound around a projection 11 of the upper partial segment 5. The yoke, opposite to the groove-key connection 7, is interrupted by an air gap which is filled by the Hall-probe 6. A control circuit is located on the circuit carrier 1 outside of the Hall probe 6. A housing 3 with a cover 12 accommodates the current sensor 2.

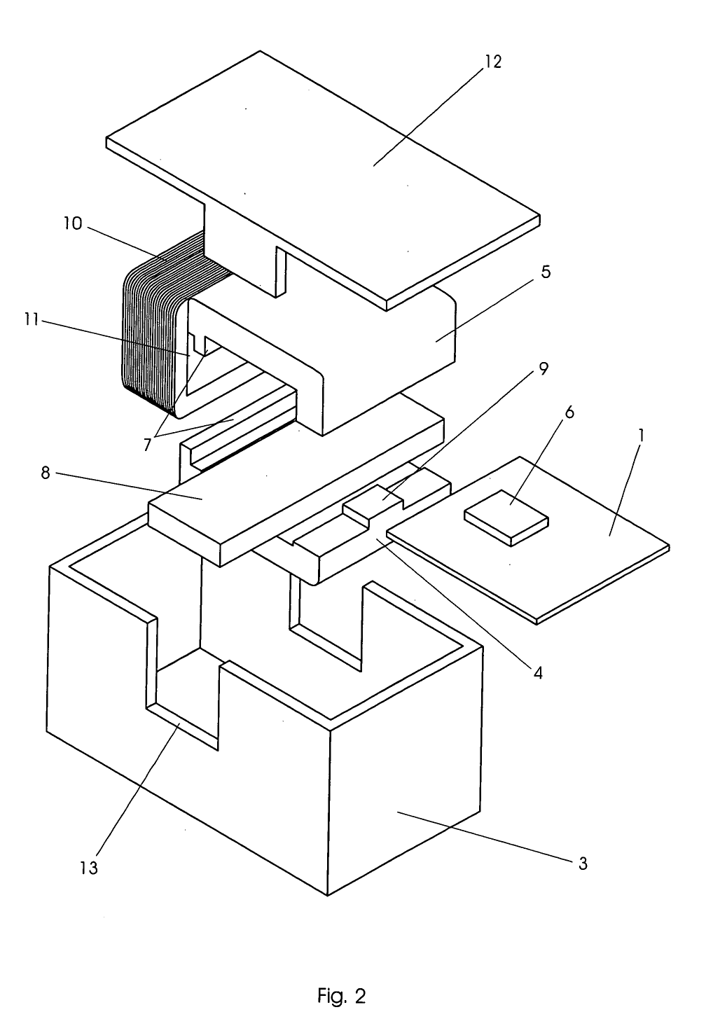

Finally, a conductor 8 extends through the yoke. It can be formed as a straight conductor rail for guiding high current intensities. It extends outwardly beyond the housing 3 at both sides. The conductor 8 is supported in lateral recesses 13 of the housing 3, as can be seen from FIG. 2.

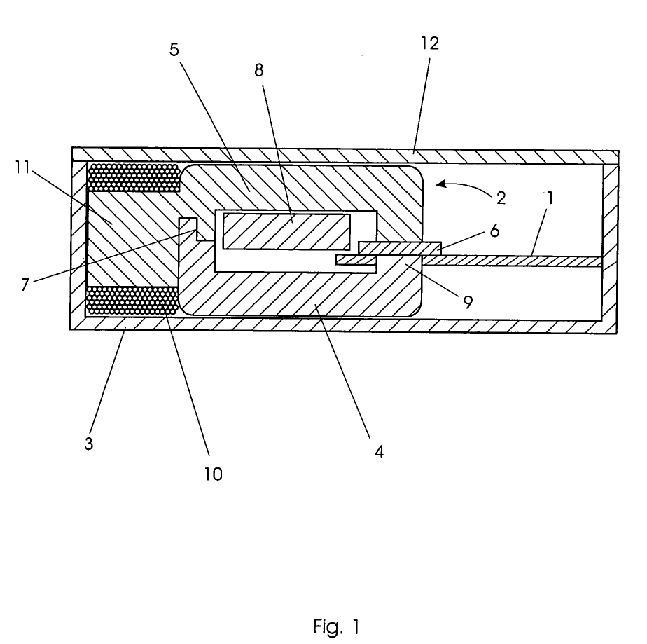

FIG. 2 shows the control device of FIG. 1 in a perspective explosive view. It can be seen that the lower partial segment 4 is provided with a pin 9 on a side which is opposite to the groove-key connection 7, on which in the assembled condition of the both partial segments 4 and 5 the air gap is located. In the circuit carrier 1 a recess is provided in correspondence with the pin 9, so that the pin 9 in the assembled condition of the current sensor 2 engages in the recess and connects the circuit carrier 1 with the pin 9. Moreover, since the pin narrows locally the air gap, it bundles the magnetic field induced by the current flowing from the conductor rail 8 in the yoke, so that the Hall probe 6 arranged in the air gap directly over this recess or the pin 9 on the circuit carrier 1, is exposed to intense magnetic field. The Hall probe 6 overlaps the recess of the circuit carrier 1. At least at the two sides of the recess it is mounted on the circuit carrier 1 by soldering, glueing or in other suitable ways.

The conductor 8, whose electrical current flow must be measured, is enclosed in the housing 3 by the partial segments 4 and 5. They extend along the conductor over the total width of the inner space of the housing 3 and screen the parts of the circuit carrier 1 located outside of the air gap from the magnetic field induced by the conductor 8. In this way, the control circuit located on the circuit carrier 1 is protected from interference actions of the current in the conductor 8.

A residual magnetization that can remain after the measurement of an intense current in the yoke, can be eliminated by the coil 10. When it is supplied with an alternating current, the residual magnetism in the yoke is eliminated. The control circuit can automatically perform the demagnetization at a suitable time point, for example before the switching to a sensitive current measurement region.

During the process of assembly of the control device, first the lower partial segment 4 is introduced in the housing 3. Then the circuit carrier 1 with the Hall probe 6 arranged on it is inserted in the housing 3 so that the pin 9 engages in the recess of the circuit carrier 1. After insertion of the conductor 8, the upper partial segment 5 with the winding 10 is placed on the lower partial segment 4 and connected with it through the groove-key connection 7. Therefore, a very simple joining process is carried out. In the inserted condition, the both partial segments 4 and 5 as well as the winding 10 are fixed and held by the housing 3. Finally, the cover 2 is placed on top and the housing 3 is closed.

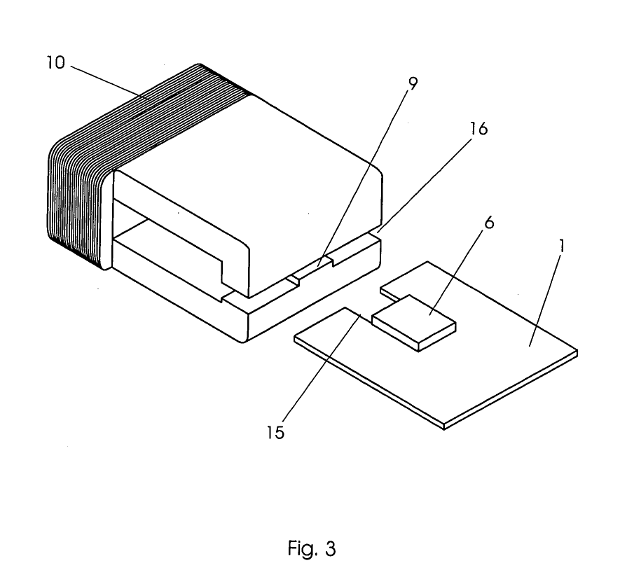

FIG. 3 shows a one-piece integral yoke 14 and a circuit carrier 1 of a further embodiment to the inventive current circuit. A Hall probe 6 is mounted on the circuit carrier as in the previous embodiment, and overlaps a recess 15 in the circuit carrier 1. However, this recess 15, in contrast to the first embodiment, has edges which are open toward the yoke. This design allows to insert the circuit carrier 1 with the Hall probe 6 from the side into the gap 16 of the yoke, so that the pin 9 provided in the air gap 16 engages, as in the first embodiment, into the recess 15. It is to be understood that it is also possible that the circuit carrier with the edge-open recess 15 of FIG. 3 can be combined with the two-part yoke, as shown in FIGS. 1 and 2.

In operation of the control device, an electric current with high current intensity passes through the conductor 8. The conductor 8 is surrounded by a magnetic field which is guided by the soft-magnetic partial segments 4 and 5 of the yoke. The magnetic flux is guided in the yoke and passes perpendicular both to the air gap and also to the circuit carrier 1 and the Hall probe 6. The Hall probe 6 detects the magnetic flux and provides the result to the control circuit. A change of the current intensity activates a direct change of the magnetic flux detected by the Hall probe 6 and supplies the control circuit with information, so that it reacts to the information in a pre-programmable way.

It will be understood that each of the elements described above, or two or more together, may also find a useful application in other types of constructions differing from the types described above.

While the invention has been illustrated and described as embodied in a current sensor with a control device, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed as new and desired to be protected by Letters Patent is set forth in the appended claims.

1. A current sensor, comprising a yoke with an air gap; a magnetic field probe arranged in said air gap; a circuit carrier on which said magnetic field probe is mounted, said magnetic field probe being mounted so that it overlaps a recess of said circuit carrier, and a magnetic flux of said yoke in said recess being oriented substantially perpendicularly to said circuit carrier.

2. A current sensor as defined in claim 1, wherein said yoke is inserted in said recess of said circuit carrier.

3. A current sensor as defined in claim 1, wherein said recess is formed as a window in said circuit carrier.

4. A current sensor as defined in claim 1, wherein said recess of said circuit carrier has an open edge.

5. A current sensor as defined in claim 1, wherein said yoke is a one-piece integral yoke.

6. A current sensor as defined in claim 1, wherein said yoke is formed as a two-part yoke.

7. A current sensor as defined in claim 6, wherein said yoke is provided with a groove-key connection.

8. A current sensor as defined in claim 1; and further comprising a conductor which extends rectilinearly through said yoke.

9. A current sensor as defined in claim 8, wherein said yoke has a pin which engages in said recess and expands outwardly in a direction of said conductor over said pin.

10. A current sensor as defined in claim 1, wherein said circuit carrier has a further processing circuit for processing measuring results produced by said magnetic field probe.

11. A current sensor as defined in claim 1, wherein said yoke has a winding for demagnetization of said yoke.
